(19) United States
(12) Patent Application Publication
(10) Pub. No.: US 2023/0084435 A1
(43) Pub. Date: Mar. 16, 2023

(54) METHOD FOR TESTING MEMORY AND MEMORY TESTING DEVICE

(71) Applicant: Changxin Memory Technologies, Inc., Hefei (CN)

(72) Inventor: Xiaodong LUO, HEFEI (CN)

(21) Appl. No.: 17/843,588

(22) Filed: Jun. 17, 2022

(30) Foreign Application Priority Data
Sep. 16, 2021 (CN) 202111085389.0

(51) Int. Cl. G11C 29/50

(52) U.S. Cl. CPC G11C 29/50004; G11C 2029/5004

(57) ABSTRACT

A method for testing a memory and a memory testing device are provided. The method for testing the memory includes writing data to a memory including a candidate storage unit, a fuse, and a redundant unit for replacing the candidate storage unit through the fuse when the candidate storage unit is determined to be defective; adjusting a temperature of the memory, and while adjusting the temperature, repeatedly refreshing the memory and recording the state of the fuse; reading the data of the memory if the temperature of the memory is stable at a predetermined temperature; and determining that the fuse is defective if the read data of the memory has an error.

### CROSS-REFERENCE TO RELATED APPLICATIONS

This application claims priority to Chinese Patent Application No.: 202111085389.0, filed on Sep. 16, 2021. The above-referenced application is incorporated herein by reference in its entirety.

### TECHNICAL FIELD

The invention relates to the technical field of integrated circuits, and particularly to a method for testing a memory and a memory testing device.

### BACKGROUND

Dynamic random-access memories (DRAMs) are semiconductor devices commonly used in electronic devices such as computers. A DRAM may consist of a plurality of storage units, each generally including a transistor and a capacitor. The gate of the transistor may be electrically connected to the word line, the source may be electrically connected to the bit line, and the drain may be electrically connected to the capacitor. The word line voltage on the word line can turn on and off of the transistor, so that data can be read from or written into the capacitor through the bit line.

Fuses are widely used in DRAMs to repair defective storage units in storage arrays, thereby improving product yields and reducing production costs. However, the additions of fuse circuits themselves require additional test procedures in DRAM product testing. Currently, there is no efficient method to test the performance of the fuses, resulting in potential quality issues for memory products in the market.

Therefore, a method that can efficiently test the fuses to screen out defective fuses and improve the yield of the memory are urgently desired.

### SUMMARY

This invention provides a method for testing a memory and a memory testing device to efficiently test the fuses to screen out defective fuses and improve the yields of the memory.

According to some embodiments, the invention provides a method for testing a memory. The method may include: writing data to a memory, wherein the memory includes a candidate storage unit, a fuse, and a redundant unit for replacing the candidate storage unit through the fuse when the candidate storage unit is determined to be defective; adjusting the temperature of the memory, and repeatedly refreshing the memory and recording the state of the fuse in the process of adjusting the temperature of the memory; reading, in response to determining that the temperature of the memory is stable at a predetermined temperature, the data of the memory; and determining, in response to determining that the read data of the memory has an error, that the fuse is defective.

According to some other embodiments, the invention further provides a memory testing device. The device may include a write circuit, a temperature regulator, a processor, a read circuit, and a controller.

The write circuit may be configured to write data to a memory. The memory may include a candidate storage unit, a fuse, and a redundant unit for replacing the candidate storage unit through the fuse when the candidate storage unit is determined to be defective.

The temperature regulator may be configured to adjust the temperature of the memory.

The processor may be configured to, in the process of adjusting the temperature, refresh the memory and record the state of the fuse.

The read circuit may be configured to read, in response to determining that the temperature of the memory is stable at a predetermined temperature, the data of the memory.

The controller may be configured to determine, in response to determining that the read data of the memory has an error, that the fuse is defective.

### BRIEF DESCRIPTION OF THE DRAWINGS

FIG. 1 is a flowchart of a method for testing a memory in an embodiment of this invention.

FIG. 2 is a schematic diagram showing the temperature change with time in an embodiment of this invention.

FIG. 3 is a schematic diagram of a storage array after a redundant unit replaces a storage unit in an embodiment of this invention.

FIG. 4 is a structural block diagram of a memory testing device in an embodiment of the invention.

### DETAILED DESCRIPTION OF THE EMBODIMENTS

Specific implementations of a method for testing a memory and a memory testing device provided by the invention will be described in detail below with reference to the accompanying drawings.

Embodiments of the invention first provide a method for testing a memory. FIG. 1 is a flowchart of a method for testing a memory in an embodiment of the invention. As shown in FIG. 1, the method for testing the memory may include the following steps S11 through S14.

In step S11, data is written to a memory to be tested. The memory may include a candidate storage unit, a fuse, and a redundant unit. The redundant unit may be configured to replace the candidate storage unit through the fuse if the candidate storage unit is determined to be defective.

In some embodiments, the memory may include a plurality of storage units arranged in a storage array. The candidate storage unit may be one storage unit of the plurality of storage units. The data may be written to the memory by: writing the data to the memory until the storge array is full. That is, the date may be written to all the storage units of the memory.

In some embodiments, the memory may be a dynamic random-access memory (DRAM), and the fuse may be an electrically programmable fuse (E-fuse).

The following description will be given by taking the fuse as the electrically programmable fuse as an example. The electric fuse may include a cathode, an anode, and a fuse link. One end of the fuse link may be connected to the cathode, and another end may be connected to the anode. The electrically programmable fuse may break down under an electromigration action. Apparently, the methods disclosed herein apply to memory with other types of fuses, and this specification is not limited in this regard.

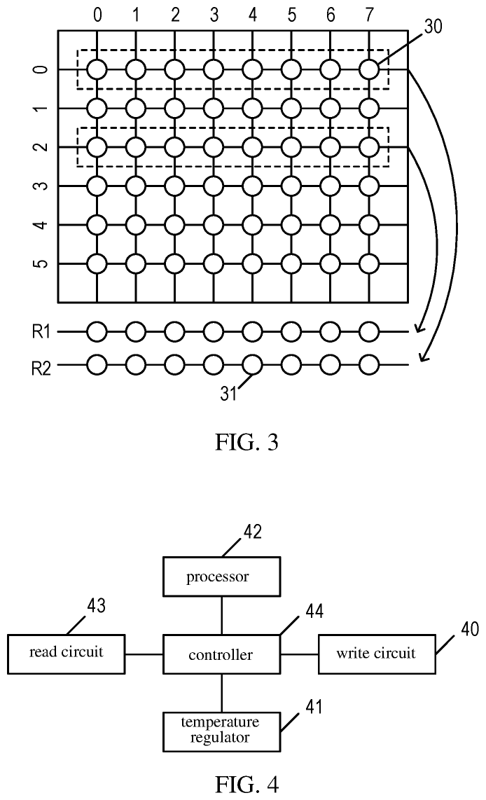

FIG. 3 is a schematic diagram of a storage array after a redundant unit replaces a storage unit in an embodiment of the invention. As shown in FIG. 3, the memory may include the storage array, and a first redundant row R1 and the second redundant row R2 located outside the storage array. The storage array may include a plurality of storage units 30 arranged in an array, and each of the first redundant row R1 and the second redundant row R2 may include a plurality of redundant units 31. For example, when the storage units 30 in the 0^{th} row and the 2^{nd} row of the storage array are determined to be defective, the 0^{th} row in the storage array may be replaced by the first redundant row R1 by breaking down the fuse, and the 2^{nd} row in the storage array may be replaced by the second redundant row R2 by breaking down the fuse to repair the storage array.

In this embodiment, after the redundant unit is used to replace the candidate storage unit in the memory when the candidate storage unit is determined to be defective, an entire storage space of the memory may be filled with the data. That is, all the storage units of the memory and the redundant unit that has replaced the candidate storage unit are filled with the data. Existing methods for determining the integrity of the storage units may be used to determine whether a storage unit is defective, and this specification is not limited in this regard.

In step S12: the temperature of the memory may be adjusted. And, in the process of adjusting the temperature of the memory, the memory may be repeatedly refreshed and the state of the fuse may be repeatedly recorded.

In this specification, the term “refresh the memory” may refer to the operation of reading data from an area of the memory and immediately rewriting the read data to the same area of the memory.

In some embodiments, adjusting the temperature of the memory may include: continuously increasing the temperature of the memory.

In some embodiments, repeatedly refreshing the memory and repeatedly recording the state of the fuse in the process of changing the temperature of the memory may include: repeatedly refreshing the memory and repeatedly recording the state of the fuse in the process of increasing the temperature of the memory.

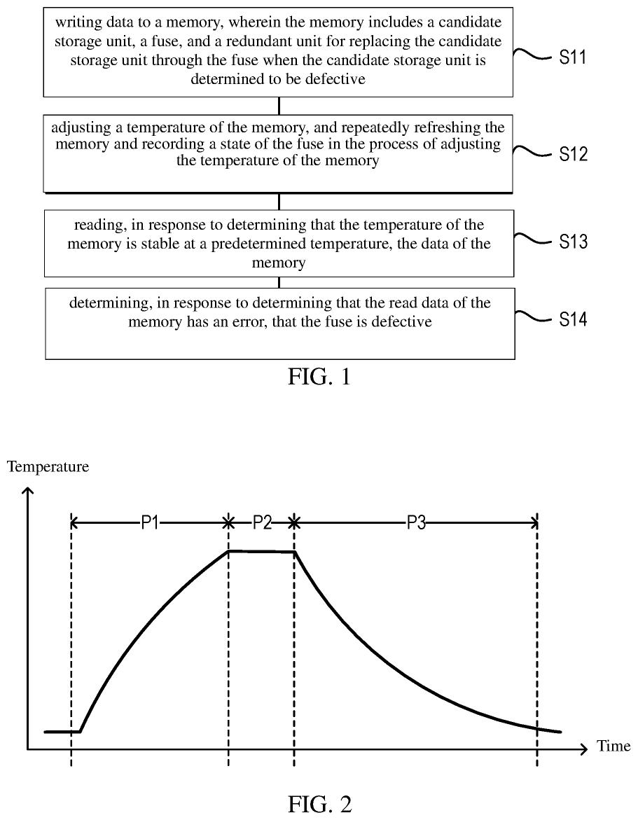

FIG. 2 is a schematic diagram showing temperature change with time in an embodiment of the invention. Specifically, in the first phase P1, as shown in FIG. 2, the temperature of the memory may be continuously increased by heating up a testing machine holding the memory. In the process of increasing the temperature of the memory (i.e., in the first phase P1), the storage array may be refreshed according to a Joint Electron Device Engineering Council (JEDEC) specification, and an operation of recording the state of the fuse into a register of the memory is performed between two consecutive refresh operations. The refresh operation and the operation of recording the state of the fuse may be performed cyclically and alternately in the process of increasing the temperature of the memory.

In some embodiments, repeatedly refreshing the memory and repeatedly recording the state of the fuse in the process of changing the temperature of the memory may include: in the process of increasing the temperature of the memory, refreshing the memory and recording the state of the fuse once every first predetermined time interval.

Specifically, in the process of increasing the temperature of the memory, the operation of refreshing the memory and the operation of recording the state of the fuse can be performed at the same time intervals for the ease of controlling the frequency of the refresh operation and the recording operation. Thus, the defective storage units can be identified more accurately and quickly. The specific value of the first predetermined time interval can be selected by those skilled in the art according to actual needs. For example, the first predetermined time interval may be 30 s, 1 min, 2 min, or 5 min, and this specification is not limited in this regard.

In some embodiments, repeatedly refreshing the memory and repeatedly recording the state of the fuse in the process of changing the temperature of the memory may include: in the process of increasing the temperature of the memory, refreshing the memory and recording the state of the fuse once every first predetermined temperature interval.

In the process of increasing the temperature of the memory, the operation of refreshing the memory and the operation of recording the state of the fuse can be performed at the same temperature intervals in order to accurately obtain the temperature that causes the state of the fuse to change (i.e., the temperature that causes the fuse to behave abnormally). The specific value of the first predetermined temperature interval can be selected by those skilled in the art according to actual needs. For example, the first predetermined temperature interval can be 1° C., 2° C., 5° C., or 10° C., and this specification is not limited in this regard.

In step S13: in response to determining that the temperature of the memory is stable at a predetermined temperature, the data of the memory may be read.

In step S14: in response to determining that the read data of the memory has an error, it is determined that the fuse is defective. In this specification, the data of the memory “has an error” may mean that the data read from the memory is different from the reference value.

In some embodiments, reading, in response to determining that the temperature of the memory is stable at a predetermined temperature, the data of the memory may include: reading, in response to determining that the temperature of the memory is stable at a first sub-predetermined temperature, the data of the storage array.

Specifically, after the temperature of the memory is stabilized at the first sub-predetermined temperature (for example, the memory reaches the second phase P2 in FIG. 2), the data in the storage array of the memory may be read. The change in the temperature of the memory may cause a change in the state of the fuse. For example, when the temperature of the memory is within a threshold temperature range, the fuse may be in an unbroken state. When the temperature of the memory reaches a threshold temperature, the fuse may change from the unbroken state to a broken state due to the presence of a defect. Since the fuse is configured for the redundant unit to replace the defective storage unit, the changes in the state of the fuse may cause errors in the read data in the redundant unit. Based on the above principles, when there is an error in the read data of the memory, it can be determined that the fuse in the memory is defective.

In some embodiments, the first sub-predetermined temperature may be in a range from 30° C. to 120° C. In an illustrated embodiment, the first sub-predetermined temperature may be 30° C., 40° C., 50° C., 88° C., or 100° C.

In some embodiments, after reading the data of the storage array in response to determining that the temperature of the memory is stable at the first sub-predetermined temperature, the method may further include: continuously reducing the temperature of the memory, and repeatedly refreshing the memory and repeatedly recording the state of the fuse in the process of reducing the temperature of the memory; and reading, in response to determining that the temperature of the memory is stable at the second sub-predetermined temperature, the data of the storage array. The second sub-predetermined temperature may be lower than the first sub-predetermined temperature.

In some embodiments, the second sub-predetermined temperature may be in a range of 10° C. to −30° C. In an illustrated embodiment, the second sub-predetermined temperature may be 10° C., 0° C., −10° C., −15° C., or −20° C.

In some embodiments, prior to reducing the temperature of the memory, the method may further include: maintaining the first sub-predetermined temperature for a preset time.

To test the full temperature range (including high and low temperatures) on the fuse in the memory, after the memory reaches the first sub-predetermined temperature through a heating process and is stable for the preset time, a temperature reduction process may be performed on the memory. That is, the memory may enter a third phase P3 in FIG. 2. In the process of reducing the temperature of the memory (i.e., in the third phase P3), the storage array may be refreshed according to the JEDEC specification, and an operation of recording the state of the fuse into the register of the memory may be performed between two consecutive refresh operations. The refresh operation and the operation of recording the state of the fuse may be performed cyclically and alternately in the process of reducing the temperature of the memory.

In some embodiments, repeatedly refreshing the memory and repeatedly recording the state of the fuse in the process of reducing the temperature of the memory may include: in the process of reducing the temperature of the memory, refreshing the memory and recording the state of the fuse once every second predetermined time interval.

In the process of reducing the temperature of the memory, the operation of refreshing the memory and the operation of recording the state of the fuse may be performed at the same time intervals for the ease of controlling the frequency of performing the refresh operation and the recording operation. Thus, the defective storage units may be identified more accurately and quickly. The second predetermined time interval may be the same as the first predetermined time interval or may be different from the first predetermined time interval.

In some embodiments, repeatedly refreshing the memory and repeatedly recording the state of the fuse in the process of reducing the temperature of the memory may include: in the process of reducing the temperature of the memory, refreshing the memory and recording the state of the fuse once every second predetermined temperature interval.

In the process of reducing the temperature of the memory, the operation of refreshing the memory and the operation of recording the state of the fuse may be performed at the same temperature intervals in order to accurately obtain the temperature causing the state of the fuse to change (i.e., the temperature causing the fuse to behave abnormally). The second predetermined temperature interval may be the same as the first predetermined temperature interval or may be different from the first predetermined temperature interval.

In some embodiments, determining, in response to determining that the read data of the memory has an error, that the fuse is defective may include: determining, in response to determining that at least one of the read data in the storage array at the first sub-predetermined temperature and the read data in the storage array at the second sub-predetermined temperature has an error, that the fuse is defective.

If the read data in the storage array at the first sub-predetermined temperature and the read data in the storage array at the second sub-predetermined temperature do not have any error, the heating process and a cooling process do not cause a change in the state of the fuse. That is, it is determined that the fuse is not defective. If at least one of the read data in the storage array at the first sub-predetermined temperature and the read data in the storage array at the second sub-predetermined temperature has an error, it is determined that the fuse is defective.

In some embodiments, the cooling rate of reducing the temperature of the memory may be less than the heating rate of increasing the temperature of the memory. This is to prevent the temperature of the memory from dropping too fast, resulting in damage to film layers of the memory.

The invention further provides a memory testing device. FIG. 4 is a structural block diagram of the memory testing device in an embodiment of the invention. The memory testing device provided in this embodiment may test a memory through the method for testing the memory as shown in FIGS. 1 to 3.

As shown in FIG. 4, the memory testing device includes a write circuit 40, a temperature regulator 41, a processor 42, a read circuit 43, and a controller 44.

The write circuit 40 may be configured to write data to a memory. The memory may include a candidate storage unit, a fuse, and a redundant unit for replacing the candidate storage unit through the fuse when the candidate storage unit is determined to be defective.

The temperature regulator 41 may be configured to adjust the temperature of the memory.

The processor 42 may be configured to repeatedly refresh the memory and repeatedly record the state of the fuse in the process of adjusting the temperature of the memory.

The read circuit 43 may be configured to determine whether the temperature of the memory is stable at a predetermined temperature and, if so, read the data of the memory.

The controller 44 may be configured to determine, in response to determining that the read data of the memory has an error, that the fuse is defective.

The specific structure of the write circuit 40 may be set by those skilled in the art according to actual needs, provided that the data can be written to the memory by the write circuit 40. The specific structure of the read circuit 43 can be set by those skilled in the art according to actual needs, provided that the read circuit 43 can determine whether the temperature of the memory is stable at a predetermined temperature and can read the data of the memory.

In some embodiments, the memory may include a plurality of storage units arranged in a storage array. One storage unit of the plurality of storage units may be the candidate storage unit replaced by the redundant unit through the fuse.

The write circuit 40 may be configured to write the data to the memory until the storge array is full. That is, the write circuit 40 may be configured to write the data to all the storage units of the memory.

In some embodiments, the temperature regulator 41 is configured to continuously increase the temperature of the memory.

In some embodiments, the processor 42 may be configured to, in the process of increasing the temperature of the memory, repeatedly refresh the storage array; and repeatedly record the state of the fuse.

In some embodiments, the processor 42 may be configured to refresh the memory and record the state of the fuse once every first predetermined time interval in the process of increasing the temperature of the memory.

In some embodiments, the processor 42 may be configured to refresh the memory and record the state of the fuse once every first predetermined temperature interval in the process of increasing the temperature of the memory.

In some embodiments, the read circuit 43 may be configured to determine whether the temperature of the memory is stable at a first sub-predetermined temperature and, if so, read the data of the storage array.

In some embodiments, the temperature regulator 41 may be further configured to continuously reduce the temperature of the memory after determining that the temperature of the memory is stable at the first sub-predetermined temperature and reading the data of the storage array.

The processor 42 may be further configured to repeatedly refresh the memory and repeatedly record the state of the fuse in the process of reducing the temperature of the memory.

The read circuit 43 may be further configured to determine whether the temperature of the memory is stable at the second sub-predetermined temperature and, if so, read the data of the storage array. The second sub-predetermined temperature is lower than the first sub-predetermined temperature.

In some embodiments, the processor 42 may be further configured to refresh the memory and record the state of the fuse once every second predetermined time interval in the process of reducing the temperature of the memory.

In some embodiments, the processor 42 may be further configured to refresh the memory and record the state of the fuse once every second predetermined temperature interval in the process of reducing the temperature of the memory.

In some embodiments, the controller 44 may be configured to determine whether the read data in the storage array at the first sub-predetermined temperature and the read data in the storage array at the second sub-predetermined temperature are both accurate, and if not, determine that the fuse is defective.

In some embodiments, the memory may be a DRAM, and the fuse may be an electrically programmable fuse.

In the method for testing the memory and the memory testing device provided by the above-mentioned embodiments of the invention, refreshing the memory and recording the state of the fuse are repeatedly performed in the process of adjusting the temperature of the memory. If the state of the fuse changes in the process of adjusting the temperature, the refresh of the memory will be performed on a different storage array, thus resulting in an error of the read data. The method for testing the memory and the memory testing device provided in the embodiments of the invention do not require additional testing procedures or extra testing time. Thus, they can efficiently screen out defective fuses, reduces the product failure rate, and improves the product yield of the memory.

The above are only some embodiments of the invention. For those of ordinary skill in the art, without departing from the principle of the invention, several improvements and modifications can also be made. These improvements and modifications should also be regarded as the scope of protection of this invention.

What is claimed is:

1. A method for testing a memory, comprising:
writing data to the memory, wherein the memory comprises a candidate storage unit, a fuse, and a redundant unit for replacing the candidate storage unit through the fuse when the candidate storage unit is determined to be defective;
adjusting a temperature of the memory, and repeatedly refreshing the memory and recording a state of the fuse in a process of adjusting the temperature of the memory;
reading, in response to determining that the temperature of the memory is stable at a predetermined temperature, the data of the memory; and
determining, in response to determining that the read data of the memory has an error, that the fuse is defective.

2. The method of claim 1, wherein the memory comprises a plurality of storage units arranged in a storage array, one storage unit of the plurality of storage units is the candidate storage unit, and wherein writing the data to the memory comprises:
writing the data to all the storage units of the memory.

3. The method of claim 2, wherein adjusting the temperature of the memory comprises:
continuously increasing the temperature of the memory.

4. The method of claim 3, wherein repeatedly refreshing the memory and recording the state of the fuse in the process of adjusting the temperature of the memory comprises:
repeatedly refreshing the memory and recording the state of the fuse in the process of increasing the temperature of the memory.

5. The method of claim 3, wherein repeatedly refreshing the memory and recording the state of the fuse in the process of adjusting the temperature of the memory comprises:
in the process of increasing the temperature of the memory, refreshing the memory and recording the state of the fuse once every first predetermined time interval.

6. The method of claim 3, wherein repeatedly refreshing the memory and recording the state of the fuse in the process of changing the temperature of the memory comprises:
in the process of increasing the temperature of the memory, refreshing the memory and recording the state of the fuse once every first predetermined temperature interval.

7. The method of claim 3, wherein reading, in response to determining that the temperature of the memory is stable at a predetermined temperature, the data of the memory comprises:
reading, in response to determining that the temperature of the memory is stable at a first sub-predetermined temperature, the data of the storage array.

8. The method of claim 7, wherein the first sub-predetermined temperature is in a range of 30° C. to 120° C.

9. The method of claim 7, wherein after reading, in response to determining that the temperature of the memory is stable at a first sub-predetermined temperature, the data of the memory, the method further comprises:
reducing the temperature of the memory, and repeatedly refreshing the memory and recording the state of the fuse in the process of reducing the temperature of the memory; and
reading, in response to determining that the temperature of the memory is stable at a second sub-predetermined temperature, the data of the memory, wherein the second sub-predetermined temperature is lower than the first sub-predetermined temperature.

10. The method of claim 9, wherein the second sub-predetermined temperature is in a range of 10° C. to −30° C.

11. The method of claim 9, wherein prior to reducing the temperature of the memory, the method further comprises:
maintaining the first sub-predetermined temperature for a preset time.

12. The method of claim 9, wherein repeatedly refreshing the memory and recording the state of the fuse in the process of reducing the temperature of the memory comprises:
in the process of reducing the temperature of the memory, refreshing the memory and recording the state of the fuse once every second predetermined time interval.

13. The method of claim 9, wherein repeatedly refreshing the memory and recording the state of the fuse in the process of reducing the temperature of the memory comprises:
in the process of reducing the temperature of the memory, refreshing the memory and recording the state of the fuse once every second predetermined temperature interval.

14. The method of claim 9, wherein determining, in response to determining that the read data of the memory has an error, that the fuse is defective comprises:
determining, in response to determining that at least one of the read data of the memory at the first sub-predetermined temperature and the read data of the memory at the second sub-predetermined temperature has an error, that the fuse is defective.

15. The method of claim 9, wherein a cooling rate of reducing the temperature of the memory is less than a heating rate of increasing the temperature of the memory.

16. The method of claim 1, wherein the memory is a dynamic random-access memory (DRAM), and the fuse is an electrically programmable fuse.

17. A memory testing device, comprising:
a write circuit configured to write data to a memory, wherein the memory comprises a candidate storage unit, a fuse, and a redundant unit for replacing the candidate storage unit through the fuse when the candidate storage unit is determined to be defective;
a temperature regulator configured to adjust a temperature of the memory;
a processor configured to, in a process of adjusting the temperature,
repeatedly refresh the memory; and
repeatedly record a state of the fuse;
a read circuit configured to read, in response to determining that the temperature of the memory is stable at a predetermined temperature, the data of the memory; and
a controller configured to determine, in response to determining that the read data of the memory has an error, that the fuse is defective.

18. The memory testing device of claim 17, wherein the memory comprises a plurality of storage units arranged in a storage array, one storage unit of the plurality of storage units is the candidate storage unit, and wherein the write circuit is configured to write the data to all the storage units of the memory.

19. The memory testing device of claim 18, wherein the temperature regulator is configured to continuously increase the temperature of the memory.

20. The memory testing device of claim 19, wherein the processor is configured to, in the process of increasing the temperature of the memory:
repeatedly refresh the storage array; and
repeatedly record the state of the fuse.
